(19) United States
(12) Patent Application Publication
(10) Pub. No.: US 2024/0203734 A1
(43) Pub. Date: Jun. 20, 2024

(54) METHODS FOR FORMING MULTILAYER STRUCTURES ON A SUBSTRATE AND RELATED MULTILAYER STRUCTURES

(71) Applicant: ASM IP Holding B.V., Almere (NL)

(72) Inventors: Maritza Mujica, Phoenix, AZ (US); Ernesto Suarez, Scottsdale, AZ (US); Amir Kajbafvala, Chandler, AZ (US); Rami Khazaka, Leuven (BE); Arum Murali, Tempe, AZ (US); Frederick Aryeetey, Phoenix, AZ (US); Yanfu Lu, Phoenix, AZ (US); Caleb Miskin, Mesa, AZ (US); Alexandros Demos, Scottsdale, AZ (US); Bibek Karki, Phoenix, AZ (US)

(21) Appl. No.: 18/540,329

(22) Filed: Dec. 14, 2023

Related U.S. Application Data
(60) Provisional application No. 63/387,689, filed on Dec. 15, 2022.

(51) Int. Cl. H01L 21/02; C30B 25/10; C30B 25/16; C30B 29/06; C30B 29/52; C30B 29/68; H01L 29/78

(52) U.S. Cl. CPC H01L 21/0262; C30B 25/10; C30B 25/16; C30B 29/06; C30B 29/52; C30B 29/68; H01L 21/02532; H01L 21/02579; H01L 29/7848; H01L 29/167

(57) ABSTRACT

Methods for forming multilayer structures are disclosed. The methods may include, seating a substrate within a chamber body, and regulating a temperature profile across an upper surface of the substrate during each individual deposition phase of multiphase deposition process. Semiconductor device structures including multilayer structures are also disclosed.

### CROSS-REFERENCE TO RELATED APPLICATION(S)

This application claims the benefit of U.S. Provisional Application 63/387,689 filed on Dec. 15, 2022, the entire contents of which are incorporated herein by reference.

### FIELD OF INVENTION

The present disclosure relates generally to the field of semiconductor processing methods and systems, and to the field of device and integrated circuit manufacture. In particular, the present disclosure generally relates to methods for forming multilayer structures as well as the multilayer structures formed by such methods.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional scaling techniques for improving device performance face major challenges at future technology nodes.

One approach to further improve semiconductor device performance is to enhance the carrier mobility by utilizing strain induced effects. For example, it has been demonstrated that hole mobility can be considerably enhanced in p-channel Group IV semiconductor transistors by employing strained source and drain regions.

Furthermore, a reduction in the contact resistance to the active regions of a semiconductor device can be desirable to improve device performance. For example, the source and drain regions of a transistor device can include a high concentrations of dopants (e.g., either p-type or n-type) to lower the contact resistance to said source and drain regions.

In addition, it can be desirable, in some applications, to selectively deposit uniform semiconductor materials, such as, for example, highly strained and/or highly doped group IV semiconductor materials, on crystalline surfaces whilst preventing, or substantially preventing, deposition on non-crystalline surfaces.

However, selective deposition processes that can achieve all of the above advantageous material properties are enormously complex, especially when considering such advantageous material properties are often desirable over the entirety of the substrate upon which deposition is performed. To maintain a uniform selective deposition process whilst depositing highly strained and/or highly doped materials can require a complex multifactorial approach to achieve optimum deposition results.

The process parameters governing successful uniform selective deposition of highly strained and/or highly doped materials can be complex due to the interaction of some, if not all, of the process parameters employed in the uniform selective deposition process. For example, the deposition parameters that can interact with one another during a uniform selective epitaxial deposition process can include, but are not limited to, process gas selection (e.g., precursor gases, dopant gases, carrier gases, and reactant gases), the process gas flow rates, the process gas flow rate ratios, as well as the complex chemical interactions between, not only the individual processes gases with each other, but also with the deposition surface of the substrate.

In addition, temperature control and particularly temperature uniformity across the upper surface of the substrate (i.e., the deposition surface) can be critical parameters in maintaining a desirable uniform selective deposition process which is capable of depositing highly strain and/or highly doped materials across the entire substrate surface.

Accordingly, improved methods for selectively forming multilayer structures which can include uniform highly strained and/or uniform highly doped regions are desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In particular, the present disclosure describes methods for depositing a multilayer structure on a substrate, the methods comprising, seating a substrate on a substrate support disposed in a chamber body, the chamber body having an upper wall and a lower wall. The methods of the present disclosure can further comprise, heating the substrate to a deposition temperature employing at least an upper heater element array supported above the upper wall of the chamber body, and providing a controller in communication with at least the upper heater element array, wherein the controller throttles power to at least the upper heater element array according to a set of optical temperature measurements communicated to the controller from at least a first pyrometer and a second pyrometer, the first pyrometer and the second pyrometer being supported above the upper heater element array and being optically coupled to the substrate surface over a first acquisition area and a second acquisition area, wherein the second acquisition area is radially distal from the first acquisition area. The methods of the present disclosure can further comprise, depositing a multilayer structure over the substrate employing a multiphase deposition process which includes at least three deposition phases comprising, epitaxially depositing a first SiGe:B layer over the substrate during a first deposition phase, epitaxially depositing a fully strained second SiGe:B layer directly over the first SiGe:B layer during a second deposition phase, and epitaxially depositing a Si:B layer directly on the fully strained second SiGe:B layer, wherein the boron concentration (atom/cm3) non-uniformity in the first SiGe:B layer, the fully strained second SiGe:B layer, and the Si:B layer is less than 3%.

In some embodiment, the upper wall of the chamber extends longitudinally between an injection end and a longitudinally opposite exhaust end, and the lower wall is below and parallel relative to the upper wall.

In some embodiment, the reaction chamber comprises an arcuate, or dome-like shape.

In some embodiment, the first SiGe:B layer has a germanium content (atomic-%) between 0.15 and 0.40 and the fully strained second SiGe:B layer has a germanium content (atom-%) between 0.40 and 0.70, and wherein the first SiGe:B layer and the fully strained second SiGe:B layer have a germanium content (atomic-%) non-uniformity of less than 0.5%.

In some embodiment, each of the first SiGe:B layer, the fully strained second SiGe:B layer, and the Si:B layer, have a thickness non-uniformity of less than 1 Angstrom.

The present disclosure also describes methods for forming a semiconductor structure, the methods comprising, seating a substrate within a chamber body, and regulating a temperature profile across an entire upper surface of the substrate to a temperature non-uniformity of less than 1° C., by employing a temperature feedback control procedure which operates during each individual phase of a multiphase deposition process, wherein the temperature feedback procedure comprises, acquiring at least two independent sets of optical temperature measurements from at least two separate areas on the upper surface of the substrate, and throttling the heating of the substrate according to a temperature differential or a temperature gradient across the upper surface of the substrate as determined by the at least two independent sets of optical temperature measurements. The methods of the present disclosure can further comprise, depositing a multilayer structure employing the multiphase deposition process, wherein the multiphase deposition process includes at least three deposition phases comprising, introducing a first precursor gas into the chamber body to epitaxially deposit a first layer comprising silicon and germanium on the substrate during a first deposition phase, introducing a second precursor gas into the chamber body to epitaxially deposition a second layer comprising silicon and germanium directly on the first layer during a second deposition phase, and introducing a third precursor gas into the chamber body to epitaxially deposit a third layer comprising silicon directly on the second layer during a third deposition phase.

In some embodiment, throttling the heating of the substrate further comprising, regulating power supplied to a upper heater element array disposed above the chamber body based on the at least two independent sets of optical temperature measurements.

In some embodiment, the at least two independent sets of optical temperature measurements comprise at least a first set of optical temperature measurements (T₁) acquired from a first acquisition area of the upper surface of substrate by a first pyrometer supported above the upper heater elements array, and at least a second set of optical temperature measurements (T₂) acquired from a second acquisition area of the upper surface of the substrate by a second pyrometer supported above the upper heater element, wherein the first acquisition area and the second acquisition area are separated from one another.

In some embodiment, the first pyrometer is arranged along a first optical axis and the second pyrometer is arranged along a second optical axis, the second optical axis being radially outward of the first optical axis.

In some embodiment, the first layer comprises a first SiGe layer and the second layer comprises a second SiGe layer, wherein the germanium content (atomic-%) in the second SiGe layer is greater than the germanium content (atomic-%) in the first SiGe layer.

In some embodiment, the first SiGe layer, the second SiGe layer, and the silicon layer are all doped with boron, wherein the boron concentration (atom/cm3) in the silicon layer is greater than the boron concentration (atom/cm3) in the second SiGe layer, and the boron concentration in the second SiGe layer is greater than the boron concentration (atom/cm3) in the first SiGe layer.

In some embodiment, the boron concentration (atom/cm3) non-uniformity in the silicon layer, the first SiGe layer, and the second SiGe layer is less than 3 percent (%).

In some embodiment, the germanium content (atomic-%) non-uniformity in the first SiGe layer and in the second SiGe layer is less than 0.5 percent (%).

In some embodiment, the first precursor gas and the second precursor gas both comprise germane (GeH₄), diborane (B₂H₆), hydrochloric acid (HCl) vapor, and at least one of silane (SiH₄), disilane (Si₂H₆), and dichlorosilane (DCS).

In some embodiment, the flow rate ratio of germane (GeH₄) flow rate to diborane (B₂H₆) flow rate into the chamber body during the both the first deposition phase and the second deposition phase remains substantially constant.

In some embodiment, the deposition temperature remains substantially constant during the first deposition phase, the second deposition phase, and the third deposition phase, of the multiphase deposition process.

In some embodiment, the second SiGe layer is fully compressively strained with no strain relaxation, and with a compressive strain value of greater than 500 Megapascals (MPa).

In some embodiment, the multiphase deposition process is a selective deposition process, wherein the selective deposition process preferentially deposits the first layer, the second layer, and third layer, over a crystalline material as opposed to depositing over a non-crystalline material, and wherein the multiphase deposition process is uniformly selective over the entire upper surface of the substrate.

Further embodiments of the present disclosure also include multilayer structures comprising, at least, a first SiGe:B layer, a fully strained second SiGe:B layer disposed directly on the first SiGe:B layer, and a Si:B layer disposed directly on the fully strained second SiGe:B layer, wherein the multilayer structure forms at least a portion of a source or drain region of a semiconductor transistor device structure and are formed by the methods of present disclosure.

Additional embodiments of the present disclosure include further multilayer structures comprising, three or more layers including at least a first boron doped SiGe layer, a fully compressively strained second boron SiGe layer disposed directly on the first boron doped SiGe layer, and a boron doped silicon capping layer disposed directly on the fully compressively strained second SiGe layer, wherein the multilayer structure forms at least a portion of a source or drain region of a semiconductor transistor device structure and are formed by the methods of the present disclosure.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrate an exemplary method in accordance with the embodiments of the disclosure;

FIG. 2 illustrates a schematic diagram of a reaction chamber arrangement including in particular, two pyrometers, and an upper heater element array in accordance with the embodiments of the disclosure;

FIG. 3 illustrates an exemplary simplified schematic diagram of a temperature control system for feedback controlling the temperature profile across an upper surface of a substrate during a multiphase deposition process in accordance with the embodiments of the disclosure;

FIG. 4 illustrates an exemplary method which includes a feedback controlled substrate surface temperature procedure employed during each deposition phase of a multiphase deposition process in accordance with the embodiments of the disclosure;

FIG. 5 illustrate a cross-sectional schematic diagram of an exemplary structure formed in accordance with the embodiments of the disclosure;

FIG. 6 illustrate an exemplary simplified diagram of a planar transistor structure including multilayer structures formed in accordance with the embodiments of the disclosure; and

FIG. 7 illustrate an exemplary simplified diagram of a FinFET transistor structure including multilayer structures formed in accordance with the embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide, for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

As used herein, the term “deposition process” can refer to the introduction of precursors (as well as optional additional process gases) into a reaction chamber to deposit a layer over a substrate. Multiphase deposition processes are examples of “deposition processes”.

As used herein, the term “epitaxial layer” can refer to a substantially single crystalline layer directly on a underlying substantially single crystalline substrate or layer.

As used herein, the term “chemical vapor deposition” can refer to any process wherein a substrate is exposed to one or more volatile precursors (as well as optional additional process gases), which react and/or decompose on a substrate surface to produce a desired deposition.

As used here, the term “silicon germanium” can refer to a semiconductor material comprising silicon and germanium and can be represented as Si₁₋ₓGeₓ wherein 1≥x≥0, or 0.8≥x≥0.1, or 0.6≥x≥0.2, or materials comprising silicon and germanium having compositions as set forth herein. In addition the term “silicon germanium” can be represented as SiGe and can further be represented as SiGe:B when said silicon germanium is doped with a boron dopant. Likewise a silicon material doped with a boron dopant can be represented as Si:B.

As used herein, the term “multiphase deposition process” can refer to a deposition process which includes multiple distinct deposition phases utilized for depositing a multilayer structure. For example, each distinct phase of a multiphase deposition process may comprise a specific deposition process for depositing an individual layer of the multilayer structure. Each deposition phase can be employed to deposit a different layer (i.e., a different material and/or composition of material), thereby building up a multilayer structure in a layer-by-layer manner. Multiphase deposition processes can be performed by employing deposition techniques such as chemical vapor deposition, plasma-enhanced chemical vapor deposition, atomic layer deposition, cyclical chemical vapor deposition, and plasma-enhanced atomic layer deposition.

As used herein, the term “precursor” can include a gas, gases, or a material or materials that can become gaseous and that can be represented by a chemical formula that includes an element which may be incorporated during a deposition process as described herein.

As used herein, a “multilayer structure” can refer to multiple layers or films overlaying one another over a surface of a substrate or within a substrate. Full devices structures or partial device structures (i.e., partially fabricated device structures) can include multilayer structures.

As used herein, the term “fully strained” can refer to an epitaxially deposited layer of a first material which is lattice matched to an underlying crystalline substrate or crystalline layer of a second material, wherein the first material is composed of a different material and/or a different composition of material, to the second material. A “fully strained” epitaxially deposited layer has not undergone strain relaxation and is therefore free, or substantially free, of strain relaxation induced dislocations.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The present disclosure includes methods for forming multilayer structures as well as the multilayer structures themselves. The methods disclosed herein can facilitate the formation of multilayer structures including at least a first SiGe layer, a fully strained second SiGe layer disposed directly over the first SiGe layer, and a Si capping layer disposed directly over the fully strained second SiGe layer. Each individual layer comprising the multilayer structures of the present disclosure can also be in-situ doped with a high concentration (atom/cm³) of boron dopants to enable a low contact resistance to said multilayer structures. In addition, the processes described herein can include highly uniform selective epitaxially deposition processes which substantially, or completely favor, epitaxial deposition on crystalline films whilst preventing, or substantially preventing, deposition on non-crystalline surfaces (e.g., amorphous, or polycrystalline surfaces).

Therefore, the embodiments of the disclosure, can enable the selective deposition of highly doped, highly strained, and highly uniform (in terms of layer thickness, layer composition, strain level, and dopant concentration) over the entirety of the deposition surface of a substrate. In addition, such multilayer structures deposited according to the embodiments of the disclosure, can be employed in semiconductor device structures, such as, for example, as the source and drain regions in a semiconductor transistor device structure.

The highly uniform layers encompassing the multilayer structures of the present disclosure can be achieved in part by the use of a novel temperature feedback control system which enables exacting control over both the substrate temperature but also the temperature uniformity over the entirety of the upper surface (i.e., the deposition surface) of the substrate throughout each individual phase of the multiphase deposition process, i.e., throughout the entire deposition of the multilayer structure.

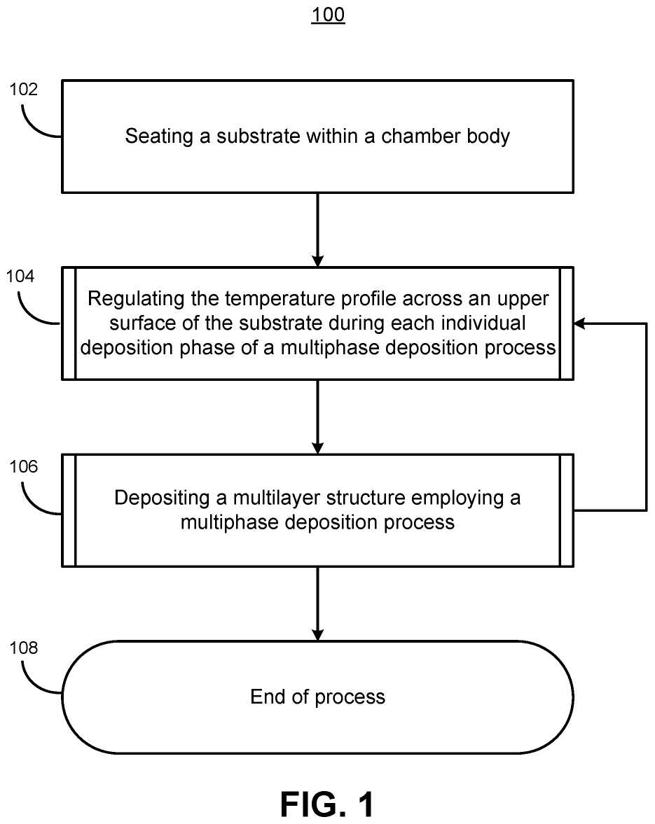

An exemplary method 100 for forming multilayer structures on the surface of a substrate according to the embodiments of the present disclosure is illustrated with reference FIG. 1. Briefly, method 100 can include the process steps of, seating a substrate within a chamber body (step 102), regulating the temperature profile across an upper surface of the substrate during each deposition phase of a multiphase deposition process (step 104), and depositing a multilayer structure by performing a multiphase deposition process (step 106). The exemplary process 100 can subsequently conclude as illustrated by the end of process step 108.

In more detail, the exemplary method 100 includes process step 102 which in some embodiments comprises, seating a substrate into a chamber body of a deposition apparatus, wherein the deposition apparatus can include a reaction chamber arrangement including an upper heater element array supported above the reaction chamber.

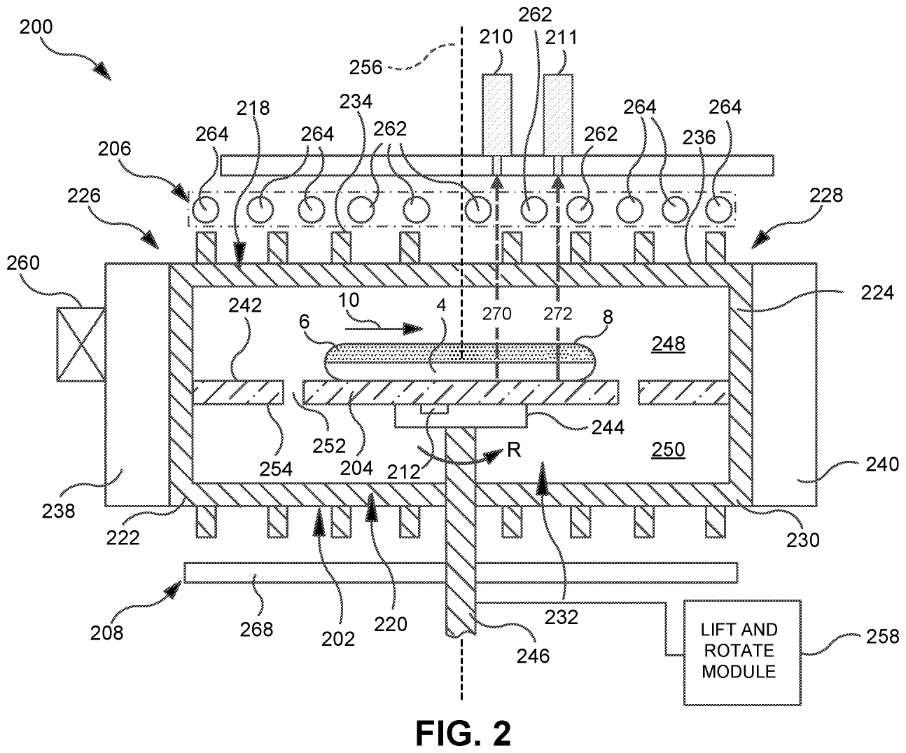

FIG. 2 illustrates an exemplary deposition apparatus and particular a reaction chamber arrangement 200 configured for performing the methods of the present disclosure.

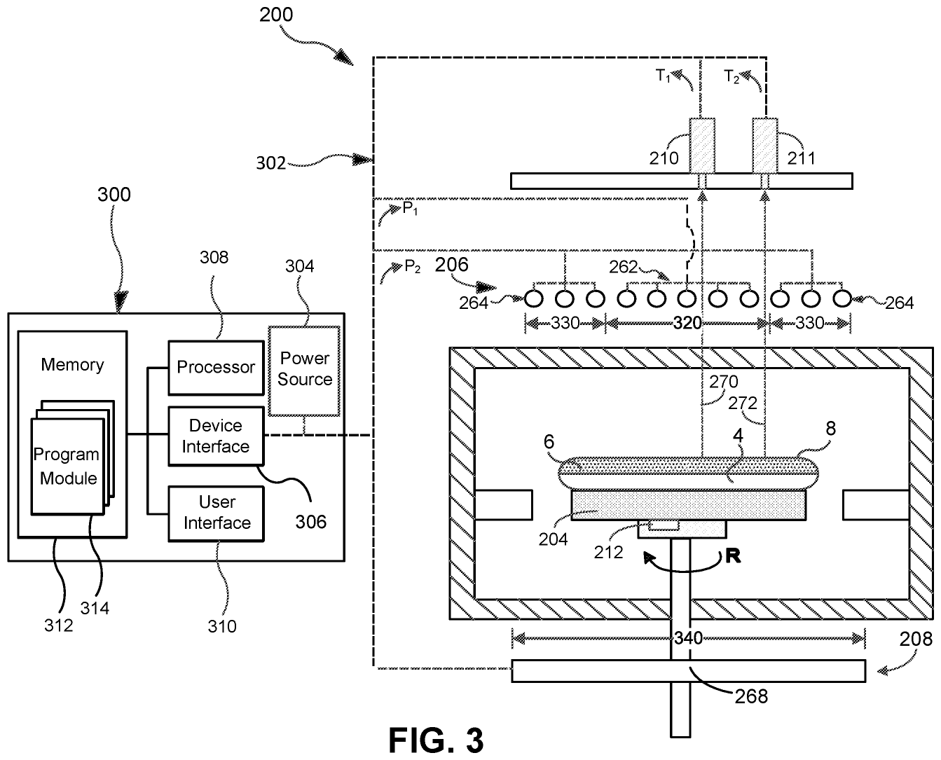

The reaction chamber arrangement 200 includes a chamber body 202 and a substrate support 204. The reaction chamber arrangement 200 can also include an upper heater element array 206 and a lower heater element array 208. The reaction chamber arrangement 200 can further include a first pyrometer 210, a second pyrometer 211, a thermocouple 212, a controller 300 (shown in FIG. 3), and a link 302 providing communication and/or power between the reaction chamber arrangement 200 and the controller 300 (FIG. 3). Although a specific arrangement is shown and described herein it is to be understood and appreciated that the reaction chamber arrangement 200 (FIG. 2) may include other elements and/or omit elements shown and described herein and remain within the scope of the present disclosure.

The chamber body 202 is configured to flow the process gases 10 across and contact the substrate 4. The chamber body 202 has an upper wall 218, a lower wall 220, a first sidewall 222, and a second sidewall 224. The upper wall 218 extends longitudinally between an injection end 226 and a longitudinally opposite exhaust end 228 of the chamber body 202, and is supported horizontally relative to gravity, and is formed from a transmissive material 230. The lower wall 220 is below and parallel relative to the upper wall 218 of the chamber body 202, is spaced apart from the upper wall 218 by an interior 232 of the chamber body 202, and is also formed from the transmissive material 230. The first sidewall 222 longitudinally spans the injection end 226 and the exhaust end 228 of the chamber body 202, extends vertically between the upper wall 218 and the lower wall 220 of the chamber body 202, and is formed from the transmissive material 230. The second sidewall 224 is parallel to the first sidewall 222, and is laterally opposite and spaced apart from the first sidewall 222 by the interior 232 of the chamber body 202, and is further formed from the transmissive material 230. In certain examples, the transmissive material 230 may include a ceramic material such as sapphire or quartz.

In accordance with certain examples, the chamber body 202 may include a plurality of external ribs 234. The plurality of external ribs 234 may extend laterally about an exterior 236 of the chamber body 202 and be longitudinally spaced between the injection end 226 and the exhaust end 228 of the chamber body 202. In certain examples, the one or more of the walls 216-222 may be substantially planar. In accordance with certain examples, one or more of the walls 216-222 may be arcuate or dome-like in shape. It is also contemplated that, in accordance with certain examples, the chamber body 202 may include no ribs.

An injection flange 238 and an exhaust flange 240 may be connected to the injection end 226 and the exhaust end 228, respectively, of the chamber body 202. The injection flange 238 may fluidly couple a process gas delivery apparatus (now shown) to the interior 232 of the chamber body 202 and be configured to provide one or more process gases to the interior 232 of the chamber body 202. The exhaust flange 240 may fluidly couple the interior 232 of the chamber body 202 to an exhaust apparatus (not shown). The exhaust flange 240 may be configured to remove any residual process gas and/or reaction byproducts from the reaction chamber arrangement 200 during deposition of the material layer(s) onto the substrate 4. In this respect the chamber body 202 may be have a cold wall, cross-flow reactor configuration, although alternative configuration can be employed.

A divider 242, a support member 244, and a shaft member 246 may be arranged within the interior 232 of the chamber body 202. The divider 242 may be fixed within the interior 232 of the chamber body 202 and divide the interior 232 of the chamber body 202 into an upper chamber 248 and a lower chamber 250. The divider 242 may further define an aperture 252 therethrough, the aperture 252 fluidly coupling the upper chamber 248 of the chamber body 202 to the lower chamber 250 of the chamber body 202. The divider 242 may be formed from an opaque material 254. The opaque material 254 may include silicon carbide.

The substrate support 204 may be configured to seat thereon the substrate 4 and can be supported at least partially within the aperture 252 for rotation R about a rotation axis 256. The substrate support 204 may seat the substrate 4 such that a radially-outer peripheral of the substrate 4 abuts the substrate support 204 while a radially-inner central portion of the substrate 4 is spaced apart from the substrate support 204. The support member 244 may be arranged below the substrate support 204 and along the rotational axis 256. The support member 244 may be further arranged within the lower chamber 250 of the chamber body 202, and fixed in rotation relative to the substrate support 204 about the rotational axis 256 for rotation with the substrate support 204. The substrate support 204 may be formed from an opaque material, such as the opaque material 230 or a graphite, or graphite coated material. The support member 244 may be formed from a transmissive material, such as the transmissive material 230.

The shaft member 246 may be arranged along the rotational axis 256 and fixed in rotation relative to the support member 244 about the rotational axis 256. The shaft member 246 may also extend through the lower chamber 250 of the chamber body 202 and through lower wall 220 of chamber body 202. The shaft member 246 may further operably connect a lift and rotate module 258 to the substrate support 204, the lift and rotate module 258 in turn configured to rotate R the substrate support 204 and the substrate 4 about the rotational axis 256 during deposition of one or more material layers 6 onto an upper surface 8 of the substrate 4. The lift and rotate module 258 may further cooperate with a gate valve 260 and a lift pin arrangement (not shown) to seat and unseat the substrate 4 from the substrate support 204, such as through a substrate handling robot arranged within a cluster-type platform in selective communication with the interior 232 of the chamber body 202 through the gate valve 260. In certain examples the shaft member 246 may be formed from a transmissive material, such as the transmissive material 230.

The upper heater element array 206 is configured to heat the substrate 4, and/or the material layer(s) 6, and the upper surface of substrate 8 (i.e., the deposition surface) during deposition of material layer(s) 6 onto the substrate 4 by radiantly communicating heat into the upper chamber 248 of the chamber body 202. In this respect the upper heater element array 206 may include the first upper heater elements 262, and the second upper heater elements 264. In some embodiments, at least one third upper heater element may be included (not shown) within the upper heater element array 206. The first upper heater elements 262 may each include a linear filament and quartz tube enclosing the linear filament and/or may include one or more bulb or lamp-type heater elements. The first upper heater elements 262 may be supported above the upper wall 218 of the chamber body 202, extend laterally between the first sidewall 222 and the second sidewall 224 of the chamber body 202, and may further overlay the substrate support 204. The second upper heater elements 264 and the optional third upper heater elements (not shown) may be similar to the first upper heater elements 262 and may additionally be longitudinally spaced apart from the first upper heater elements 262, and may further be longitudinally spaced apart from the rotational axis 256. The second upper heater elements 264 may further overlay (e.g., intersect) a peripheral edge of the substrate 4. In certain examples, the upper heater element array 206 may include eleven (11) or twelve (12) upper heater elements. Each upper heater element of the upper heater element array 206 may be longitudinally spaced apart from one another above the upper wall 218 of the chamber body 202 between the injection end 226 and the exhaust end 228 of the chamber body 202.

The lower heater element array 208 is similar to the upper heater element array 206 and is also configured to heat the substrate 4 and/or the material layer(s) 6 during deposition onto the surface 8 of the substrate 4. In this respect the lower heater element array 208 may be configured to communicate radiant heat into the lower chamber 250 of the chamber body 202 to the substrate support 204 and the divider 242. The substrate support 204 and the divider 242 may in turn heat the substrate 4 by conducting the heat through the bulk material forming the substrate support 204 and the divider 242. Radiant heat communicated into the lower chamber 250 by the lower heater element array 208 thereby being conducted to the substrate 4. The lower heater element array 208 may include a first lower heater element 268 and at least one second lower heater element (not shown).

FIG. 2 illustrates the lower heater array 208 includes an exemplary first lower heater element 268 which is similar to the first upper heater element 262 and is additionally supported below the lower wall 220 of the chamber body 202. The first lower heater element 268 further extends longitudinally between the injection end 226 and the exhaust end 228 of the chamber body 202. The first lower heater element 268 may further be substantially orthogonal relative to the first upper heater elements 262 of the upper heater element array 206. The lower heater array 208 can include at least one second lower heater element (not shown) that may be parallel to the first lower heater element 268 and laterally spaced apart from the first lower heater element 268 below the lower wall 230 of the chamber body 202. In certain examples, the first lower heater element 268 may underlie the substrate support 204. In accordance with certain examples, the at least one second lower heater element (not shown) may underlie the divider 242. It is also contemplated that, in accordance with certain examples, the lower heater element array 208 may include eleven (11) or twelve (12) lower heater elements each laterally spaced apart from one another below the lower wall 220 of the chamber body 202.

In some embodiments, a first pyrometer 210 can be configured to acquire a first set of optical temperature measurements (T₁) using electromagnetic radiation emitted by the substrate 4, the material layer(s) 6, and particularly from the upper surface of the substrate 8. In this respect the first pyrometer 210 is supported above the upper wall 218 of the chamber body 202 and is arranged along an optical axis 270 (shown in FIG. 2). More specifically, the first pyrometer 210 is supported above the upper heater element array 206 and arranged longitudinally between the injection end 226 and the exhaust end 228 of the chamber body 202 such that the optical axis 270 may extend between the first upper heater element 262 and an adjacent upper heater element. The optical axis 270 may further intersect the substrate support 204. The optical axis 270 may intersect the substrate 4 when seated on the substrate support 204, the first set of optical temperature measurements (T₁) thereby acquired by the pyrometer 270 can be acquired directly from the upper surface 8 of the substrate 4 and/or the material layer(s) 6 during deposition onto the substrate 4. In certain examples, the optical axis 270 may be coaxial with the rotational axis 256. In accordance with certain examples, the first pyrometer 210 may be at least one of longitudinally offset and/or laterally offset from the rotational axis 256, e.g., radially offset from the rotation axis 256 (as illustrated in FIG. 2). As will be appreciated by those of skill in the art in view of the present disclosure, offsetting the optical axis 270 from the rotational axis 256 may facilitate packaging the first pyrometer 210 above the chamber body 202. Examples of suitable pyrometers include OR400M optical infrared pyrometers, available from the Advanced Energy Corporation of Denver, Colorado.

In some embodiments, a second pyrometer 211 can be arranged along a second optical axis 272 and can be arranged radially outward of the first pyrometer 210 relative to the rotational axis 256. It is contemplated that the second optical axis 272 intersects the substrate support 204. More specifically, the second optical axis 272 may intersect the substrate 4 when seated on the substrate support 204, the second pyrometer 211 can thereby be configured to generate a second set of optical temperature measurements (T₂) from the substrate 4 and particular from the substrate surface 8 during deposition of the material layer(s) 6 onto the substrate 4. In certain examples, the second optical axis 272 may be laterally offset from the first optical axis 270. In accordance with certain examples, the second optical axis 272 may be longitudinally offset from the first optical axis 270. It is also contemplated that the second optical axis 272 may be both laterally offset and longitudinally offset from the first optical axis 270. Therefore, the first pyrometer 210 and the second pyrometer 211 can acquire two independent sets of optical temperature measurements (T₁ and T₂) from two separate areas on the upper surface of the substrate. For example, the first pyrometer may be optically coupled over a first acquisition area of the upper surface of the substrate, and the second pyrometer may be optically coupled over a second acquisition area over the upper surface of the substrate, wherein the second acquisition area is radially distal from the first acquisition area.

In additional and/or alternative embodiments, a third pyrometer may also be employed and may be configured as described with reference to the first pyrometer 210 and the second pyrometer 211. In such embodiments, a third pyrometer may be positioned above the upper heater array 206 to enable a third optical axis that may be longitudinally and/or radially offset from both the first pyrometer 210 and the second pyrometer 211. It is also anticipated that multiple pyrometers, such as, for example, a forth, a fifth, or even a sixth pyrometer etc., may be employed as described herein to enable profiling of the surface temperature of the substrate at multiple areas across the entire surface of the substrate.

Referring back to the exemplary method 100 (FIG. 1), once a substrate is seated within the chamber body, and particular once the substrate 4 is seated upon the substrate support 204 (FIG. 2), the exemplary method 100 (FIG. 1) may proceed by, regulating the temperature profile across an upper surface of the substrate during each phase of a multiphase deposition process by employing a feedback control procedure (step 104). For example, regulating the upper surface temperature of the substrate during each individual phase of a multiphase deposition process may comprise, acquiring at least two independent sets of optical temperature measurements from at least two separate areas on the upper surface of the substrate, and throttling the heating of the substrate according to a temperature differential or a temperature gradient across the upper surface of the substrate as determined by the at least two independent sets of optical temperature measurements.

In more detail, FIG. 3 illustrates a simplified version of the reaction chamber arrangement 200 (FIG. 2) and highlights the apparatus and methods employed in the feedback control procedure for controlling the temperature profile across the upper surface of the substrate during each distinct phase of the multiphase deposition process. For example, a controller 300 is connected to the upper heater element array 206 and, in some embodiments, the lower heater element array 208. In this respect the link 302 may connect the controller 300 to the upper heater element array 206 and, in some embodiments, to the lower heater element array 208.

In certain examples, one or more upper silicon controlled rectifier (SCR) devices (not shown) may couple the controller 300 to the upper heater element array 206. In accordance with certain examples, a singular one of the one or more upper SCR devices couples each of the upper heater elements of the upper heater element array 206 to both the controller 300 and a power source 304. The power source 304 may be integrated within the controller 300 or alternatively may be an independent unit in communication with both the controller 300 as well as being in communication with the upper heater array 206 and the lower heater array 208 and configured to supply/regulate power to both the upper heater array element 206 and the lower heater array element 208. The controller 300 thereby can be configured to have discrete control over power applied to each of the upper heater elements of the upper heater element array 206. The lower heater element array 208 may be similarly controlled by controller 300 as described above.

It is contemplated that the controller 300 can be connected to both the first pyrometer 210 and the second pyrometer 211, for example, by the link 302. In this respect the controller 300 may operatively connect the first pyrometer 210 and the second pyrometer 211 to the upper heater element array 206. Power applied to (and thereby radiant heat output) from the upper heater element array 206 can be throttled according to the two independent sets of optical temperature measurements (T₁ and T₂) provided to the controller 300 from the first pyrometer 210 and the second pyrometer 211. For example, the first pyrometer 210 can be configured to acquire a first set of optical temperature measurements (T₁) acquired from a first acquisition area on the upper surface 8 of the substrate 4, and the second pyrometer can be configured to acquire a second set of optical temperature measurements (T₂) acquired from a second acquisition area on the upper surface 8 of the substrate 4, wherein the first acquisition area and second acquisition area are separated from one another.

In additional and/or alternative embodiments, a thermocouple 212 can be linked to the lower heater element array 208, and power applied to (and thereby radiant heat output) from the lower heater element array 208 can be throttled by a set of tactile temperature measurements provided to the controller 300 by the thermocouple 212.

As will be appreciated by those of skill in the art in view of the present disclosure, throttling heat output of the upper heater element array 206 using the first pyrometer 210 and the second pyrometer 211 (and in some embodiments throttling heat output of the lower heater element array 208 by employing thermocouple 212) may limit (or eliminate) oscillations which can otherwise cause heating of substrate 4 that could otherwise be associated with lag in arrival of heat from the lower heater element array 208 at the substrate 4 through the thermal mass of the substrate support 204.

In certain examples, the heat output of the upper heater element array 206 may be exclusively throttled using the two sets of optical temperature measurements (T₁ and T₂) provided by the first pyrometer 210 and the second pyrometer 211, and the heat output of the lower heater element array 208 may be exclusively throttled by the tactile temperature measurements provided by the thermocouple 212. It is also contemplated that hybrid throttling schemes may be employed, e.g., with weighting assignments, and remain within the scope of the present disclosure.

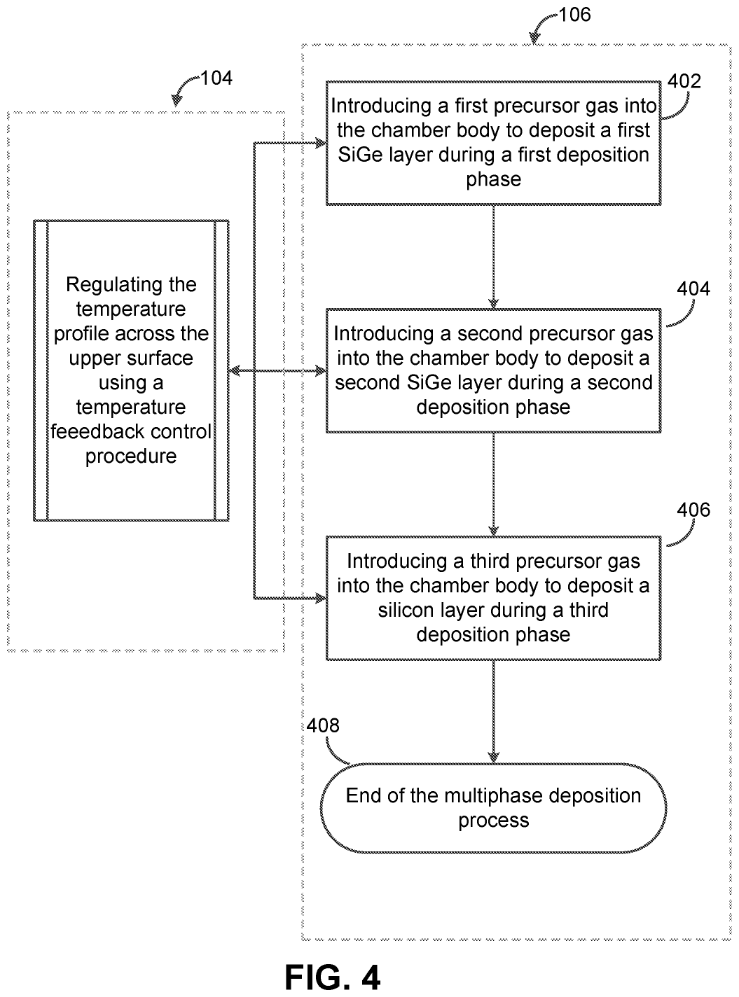

The exemplary controller 300 (FIG. 3) can include a device interface 306, a processor 308, a user interface 310, and a memory 312. The device interface 306 can connect the processor 308 to the link 302. The processor 308 is operably connected to the user interface 310 (e.g., to receive user input and/or provide user output therethrough) and is disposed in communication with the memory 312. The memory 312 includes a non-transitory machine-readable medium having a plurality of program modules 314 recorded thereon containing instructions that, when read by the processor 308, cause the processor 308 to execute certain operations. Among the operations are operations of a material layer deposition method 100 (shown in FIG. 1 and in greater detail in FIG. 4), as will be described herein. As will be appreciated by those of skill in the art in view of the present disclosure, the controller 300 may have a different arrangement in other examples and remain within the scope of the present disclosure.

In some embodiments, it is contemplated that the first upper heater elements 262 be operatively associated with the first pyrometer 210, and that the second upper heater elements 264 be operatively associated with the second pyrometer 211. In some embodiments, the lower heater element array 208 can be operatively associated with the thermocouple 212.

In this respect the first pyrometer 210 can be connected to the controller 300, for example through the link 302, and can be configured to provide a first set of optical temperature measurements (T₁) to the controller 300. In addition, the second pyrometer 211 can be connected to the controller 300, for example through the link 302, and can be configured to provide a second set of optical temperature measurements (T₂) to the controller 300.

During the deposition of the material layer(s) 6 onto the substrate 4 the controller 300 may assign the first upper heater elements 262 to a first upper heating zone, and assign the second upper heater elements 264 to a second upper heating zone. The controller 300 can be configured to receive the first set of optical temperature measurements (T₁) from the first pyrometer 210, and also receive the second set of optical temperature measurement (T₂) from the second pyrometer 211. In some embodiments, a third set of tactile temperature measurements can be acquired from the thermocouple 212.

The controller 300 can then be configured to compare the first set of optical temperature measurements (T₁) to a predetermined first upper heating zone targets, and compare the second set of optical temperature measurements (T₂) to a predetermined second upper heating zone targets. In some embodiments, the controller 300 can be configured to further compare the tactile temperature measurement to a predetermined lower heating zone targets.

When any one of the comparisons is outside of a predetermined differential limit, the controller 300 may change power applied to first upper heater elements 262, and/or power applied to the second upper heater elements 264 based on the differential. For example, in some embodiments of the disclosure, throttling heat generated by the upper heater element array 206 may comprise, throttling heating of the substrate according to a temperature differential or a temperature gradient across an upper surface of the substrate 8 determined using the first set of optical temperature measurements (T₁) and the second set of optical temperature measurements (T₂).

In certain examples, each of the upper heater elements of the upper heater element array 206 may be distributed into a first upper heating zone 320 and second upper heating zones 330. For example, the first upper heating zone 320 may comprise a central heating zone and second heating zones 330 may comprise edge heating zones. For example, a plurality of first upper heater elements 262 (e.g., five (5) or more upper heater elements) of the upper heater element array 206 may be assigned to the first upper heating zone 320 and can be throttled using the first set of optical temperature measurements (T₁), and six (6) or more second upper heater elements 264 may be assigned to the second upper heating zones 330 and throttled using the second set of optical temperature measurements (T₂). In some embodiments of the disclosure, each of the lower heater elements may be assigned to a lower heating zone 340 and throttled using the a set of tactile temperature measurements provided by the thermocouple 212. In this respect each of lower heater elements included in the lower heater element array 108 may be assigned to a lower heating zone 340.

As will be appreciated by those of skill in the art in view of the present disclosure, in addition to the aforementioned advantages relating to limiting feedback associated with changes made to heat output from lower heater elements assigned to the lower heater element array 208, assigning the upper heater elements into the first upper heating zone 320 and the second upper heating zones 330 allows for controlling temperature variation between the center and the edge of the substrate 4 and particular the upper surface of the substrate 8. For example, a predetermined first upper heating zone target may be assigned to the first upper heating zone 320, and a predetermined second upper heating zone target may be assigned to the second upper heating zones 330, and a temperature difference between the center and the edge of the substrate 4 limited (or a non-zero differential maintained) during deposition of the material layer 6 onto the upper surface 8 of the substrate 4 can be accounted for and corrected by throttling power P₁ and P₂ (FIG. 3) to the first upper heater elements 262 (P₁) and second upper heater elements 264 (P₂). Driving a temperature differential across the substrate 4 by using the first set of optical temperature measurements (T₁) and the second set of optical temperature measurement (T₂) may, in certain examples, be employed in maintaining optimum materials deposition characteristics, including but not limited to, preserving a material layer profile, composition, thickness uniformity, doping concentration uniformity, and/or to prevent edge roll-up or edge roll-down, or other characteristic of the material layer(s) being deposited in the chamber arrangement 200.

Referring back to the exemplary method 100 (FIG. 1), once a substrate is seated within the chamber body (step 102), and the substrate surface temperature feedback control procedure (step 104) is engaged, the exemplary method 100 may proceed by, depositing a multilayer structure on the substrate by employing a multiphase deposition process (step 106).

In brief, the exemplary multiphase deposition process 106 of the present disclosure can include at least three distinct deposition phases comprising, introducing a first precursor gas into the chamber body to epitaxially deposit a first layer comprising silicon and germanium on the substrate during a first deposition phase, introducing a second precursor gas into the chamber body to epitaxially deposit a second layer comprising silicon and germanium directly on the first layer in a second deposition phase, and introducing a third precursor gas into the chamber body to epitaxially deposit a third layer comprising silicon directly on the second layer in a third deposition phase. In some embodiments, the multiphase deposition process 106 of the present disclosure can also include at least three distinct deposition phases comprising, epitaxially depositing a first boron doped silicon germanium layer (i.e., a first SiGe:B layer) directly on the substrate in a first deposition phase, epitaxially depositing a fully strained second boron doped silicon germanium layer (i.e., a fully strained second SiGe:B layer) directly on the first SiGe:B layer in a second deposition phase, and epitaxially depositing a boron doped silicon layer (a Si:B layer) directly on the fully strain second SiGe:B layer in a third deposition phase.

It should be noted that in exemplary method 100 (FIG. 1) the multiphase deposition process 106 is illustrated as being in a feedback loop with process step 104. This feedback loop is illustrated to indicate that the feedback temperature control procedure for controlling the temperature of the upper surface of the substrate (as described herein above) is engaged throughout each of the individual deposition phases of the multiphase deposition process 106.

In more detail, FIG. 4 illustrates an exemplary multiphase deposition process 106, which in this non-limiting example includes three individual deposition phases (a first deposition phase 402, a second deposition phase 404, and a third deposition phase 406). It should be noted that the multiphase deposition processes of the present disclosure are not limited to three individual deposition phases and may include more or less individual deposition phases depending on the desired multilayer structure to be deposited. Since the temperature feedback control process step 104 has been described in detail herein above it is described in brief herein below when relevant to the exemplary multiphase deposition process 106 (and the constituent individual deposition phases 402, 404, and 406).

The multiphase deposition process 106 may commence with a first deposition phase 402 which comprises, introducing a first precursor gas into the chamber body to epitaxially deposit a first layer comprising silicon and germanium on the substrate. In some embodiments, the first deposition phase 402 may comprise, in-situ doping of the first layer, and in such embodiments, the first deposition phase 402 can comprise, epitaxially depositing a first boron doped silicon germanium layer (the first SiGe:B layer) directly on the substrate.

In more detail, the first deposition phase 402 can include heating the substrate, and particularly the upper surface of the substrate, to a desired deposition temperature within the chamber body. In some embodiments of the disclosure, the first deposition phase 402 includes heating the substrate to a temperature of less than 750° C., or to a temperature of less than 650° C., or to a temperature of less than 600° C., or to a temperature of less than 550° C., or to a temperature of less than 500° C., or to a temperature of less than 450° C., or even to a temperature of less than 400° C. For example, in some embodiments of the disclosure, the substrate (and particularly the upper surface of the substrate) can be heated to a deposition temperature between 400° C. and 750° C., or between 450° C. and 650° C.

In addition to controlling the temperature of the substrate, the pressure within the chamber body may also be regulated. For example, in some embodiments of the disclosure, the pressure within the chamber body during the first deposition phase 402 may be less than 760 Torr, or less than 350 Torr, or less than 100 Torr, or less than 50 Torr, or less than 25 Torr, or less than 10 Torr, or even less than 5 Torr. In some embodiments, the pressure in the chamber body during the first deposition phase 402 can be between 5 Torr and 760 Torr, or between 10 Torr and 200 Torr, or between 10 Torr and 40 Torr.

In some embodiments, the substrate temperature and the pressure within the chamber body employed during the first deposition phase 402, the second deposition phase 404, and the third deposition phase 406 (of the multiphase deposition process 106) can be substantially maintained throughout the entirety of the deposition process. In some embodiments, the temperature of the upper surface of the substrate is substantially maintained during the entire multiphase deposition process 106 such that the methods of the disclosure regulate the temperature profile across the entire upper surface of the substrate (i.e., the deposition surface) to within a temperature non-uniformity of less than 2.0° C., or less than 1.5° C., or less than 1° C., or less than 0.5° C., or less than 0.2° C., or between 2.0° C. and 0.2° C.

In alternative embodiments, the substrate temperature and the pressure within the chamber body may be adjusted between each individual deposition phase of the multiphase deposition process depending on the needs of the materials being epitaxially deposited by the multiphase deposition process 106.

Each individual deposition phase (402, 404, and 406) of the multiphase deposition process 106 (FIG. 4) can modify the environment within the chamber body. For example, the thermal environment within the chamber body can be altered by the introduction of different process gases and/or by the introduction of process gases at different flow rates, where the process gases can include at least, precursor gases, dopant gases, reactant gases, and carrier gases.

For example, the process gases introduced into the chamber body can have different thermal conductivities, as well as being introduced into the chamber body at different initial temperatures to that already established within the chamber body. Therefore, the introduction of process gases into the chamber body can alter the temperature within the chamber body, which can in turn, change the substrate temperature, and particularly the temperature of the upper surface of the substrate upon which deposition is to be performed (i.e., the deposition surface). Therefore, and as illustrated in FIG. 4, the feedback control procedure for regulating the temperature profile of the upper surface of the substrate (step 104), as previously described herein above, can be engaged continuously throughout each individual deposition phase (402, 404, and 406) of the multiphase deposition process 106 to maintain a desired temperature/temperature uniformity across the upper surface of the substrate as different process gases and/or different flow rates of process gases are introduced into the chamber body and environmental conditions vary within the chamber body.

Once the substrate temperature (i.e., the temperature across the upper surface of the substrate) and the chamber pressure have been regulated, the first deposition phase 402 (FIG. 4) can continue by introducing a first precursor gas into the chamber body to epitaxially deposit a first layer comprising silicon and germanium on the substrate. For example, the first deposition phase 402 may comprise, epitaxially depositing a first boron doped silicon germanium layer (a first SiGe:B layer) directly on the substrate.

In some embodiments, introducing the first precursor gas into the chamber body (during the first deposition phase 402) may comprise, introducing at least, one or more silicon containing gases, one or more germanium containing gases, one or more boron dopant gases, and one or more chlorine containing gases. All of the above process gases can also be introduced with or without a carrier gas, such as, for example, a hydrogen (H₂) gas.

For example, a silicon precursor, a germanium precursor, a boron dopant gas, and a chlorine containing gas, can be provided to a gas distribution assembly (not shown) at the injection end 226 (FIG. 2) of the reaction chamber assembly 200, e.g., through one or more gas injectors, such as multi-port injectors (MPIs), including a plurality of individual port injectors for providing a gas mixture into the reaction chamber. Various combinations of the precursors/reactants/dopants can be supplied to one or more of the individual port injectors to fine tune concentration profiles as desired. The silicon precursor(s), the germanium precursor(s), the boron dopant gas(es), and the chlorine containing gas(es) can be provided to the reaction chamber, such that gas phases of the precursors/reactants/dopants are provided into the chamber for an overlapping period. For example, precursors/reactants/dopants can be provided to the reaction chamber for substantially the same period.

Exemplary silicon precursors include silanes and silicon halides. In some embodiments, the silicon halide compound can include, for example, a silicon halide having the general formula given as: SiₓW_{y}H₂, wherein “W” is a halide selected from the group consisting of Fluorine (F), Chlorine (Cl), Bromine (Br), and Iodine (I), “x” and “y” are integers greater than zero, and “z” is an integer greater than or equal to zero. In some embodiments, the silicon halide precursor may be selected from the group consisting of silicon fluorides (e.g., SiF₄), silicon chlorides (e.g., SiCl₄), silicon bromides (e.g., SiBr₄), and silicon iodides (e.g., SiI₄). In some embodiments, the silicon halide precursor may comprise silicon tetrachloride (SiCl₄). In some embodiments, the silicon halide precursor may comprise a silane, such as, for example, silane (SiH₄), disilane (Si₂H₆), trisilane (Si₃H₈), tetrasilane (Si₄H₁₀), or higher order silanes with the general empirical formula SiₓH(₂ₓ₊₂).

By way of examples, the silicon precursor can be or include one or more of silicon tetrachloride (SiCl₄), trichloro-silane (SiCl₃H), dichlorosilane (SiCl₂H₂), monochlorosilane (SiClH₃), hexachlorodisilane (HCDS), octachlorotrisilane (OCTS), a silicon iodide, a silicon bromide; or an amino-based precursor, such as hexakis(ethylamino)disilane (AHEAD) and SiH[N(CH₃)₂]₃(3DMASi), a bis(dialkylamino)silane, such as BDEAS (bis(diethylamino)silane); a mono(alkylamino)silane, such as di-isopropylaminosilane; or an oxysilanes-based precursor, such as tetraethoxysilane Si(OC₂H₅)₄.

In some embodiments, the silicon precursor can include two or more precursors, such as a halogenated precursor (e.g., a silicon halide compound noted above) and a silane precursor. By way of example, the silicon precursor can include dichlorosilane and silane.

Exemplary germanium precursors can include germanes, such as germane (GeH₄), digermane (Ge₂H₆), trigermane (Ge₃H₈), or germylsilane (GeH₆Si), and halogen compounds, such as GeBr₄ or other suitable germanium-containing precursor. By way of examples, the germanium precursor can include one or more of germane and germanium tetrachloride (GeCl₄) or GeClₓH₄₋ₓ.

Exemplary boron dopant gases can include at least one of, diborane (B₂H₆), boron trichloride (BCl₃), boron trifluoride (BF₃), and deuterium-Diborane (B₂D₆).

Exemplary chlorine containing gases can include hydrochloric acid vapor (HCl), and chlorine gas (Cl₂).

Volumetric flow rates and flow ratios of the silicon precursors, the germanium precursors, the boron dopant gases, and the chlorine containing gases can vary in accordance with the desired composition of the first layer during the first deposition phase 402. By way of example, a flow rate of a silicon precursor can be between 10 sccm to 1000 sccm, or between 10 sccm to 500 sccm, or even between 10 sccm to 200 sccm. In addition, a flow rate of a germanium precursor can be between 10 sccm to 1000 sccm, or between 10 sccm to 250 sccm, or between 10 sccm to 100 sccm. In some embodiments, a flow rate of a boron dopant gases can be between 0.1 to 100 sccm, or between 0.2 sccm and 30 sccm, or even between 0.3 sccm and 15 sccm. In some embodiments, a flow rate of a chlorine-containing gas can be between 5 to 500 sccm, or between 10 sccm and 400 sccm, or even between 10 sccm and 300 sccm. It should be noted that all of the above flow rates for the various process gases utilized during the first deposition phase can be with, or without, a carrier gas.

In some embodiments, the first precursor gas may comprise, germane (GeH₄), diborane (B₂H₆), hydrochloric acid (HCl) vapor, and at least one of silane (SiH₄), disilane (Si₂H₆), and dichlorosilane (DCS). In some embodiments, the flow rate ratio of the germane (GeH₄) flow rate to the diborane (B₂H₆) flow rate into the chamber body during the first deposition phase 402 remains substantially constant. For example, in some embodiments, the flow rate ratio of the germane (GeH₄) flow rate to the diborane (B₂H₆) flow rate remains substantially constant with a deviation away from a constant flow ratio of less than 10%, or less than 8%, or less than 6%, or less than 4%, or less than 2%, or less than 1%, or less than 0.5%, or even less than 0.1%.

In some embodiments, the first layer can comprise a first SiGe:B layer, which may form as a crystalline (e.g., monocrystalline) material overlying at least a portion of the surface of the substrate. Accordingly, at least a portion of the first layer may be monocrystalline and serve as a template for further epitaxial layers. In some cases, the entire first layer may be monocrystalline. In some embodiments, the first layer can comprise a boron doped silicon germanium layer (i.e., the first SiGe:B layer) which can be epitaxially deposited directly on an underlying silicon (Si) substrate. In such embodiments, the first SiGe:B layer can be epitaxially deposited in a fully strained state directly on the underlying silicon (Si) substrate, i.e., the first SiGe:B layer is epitaxially deposited directly on the silicon (Si) without strain relaxation and without the formation of any dislocations resulting from said strain relaxation.

In some embodiments, the average layer thickness of the first SiGe:B epitaxially deposited during the first deposition phase 402 (FIG. 4) can be less than 50 nanometers, or less than 40 nanometers, or less than 30 nanometers, or less than 20 nanometers, or less than 10 nanometers, or even less than 5 nanometers. In some embodiments, the average layer thickness of the first SiGe:B layer can be between 5 nanometers and 50 nanometers, or between 20 nanometers and 40 nanometers, or between 25 nanometers and 35 nanometers. In some embodiments, the first SiGe:B layer can have a thickness non-uniformity of less than 2 Angstroms, or less than 1 Angstroms, or less than 0.5 Angstroms, or between 0.5 Angstroms and 2 Angstroms.

In some embodiments, the first SiGe:B layer can include an atomic percentage (at-%) of silicon between 60 to 80 at-%, or between 60 to 90 at-%, or even between 60 at-% to 99 at-%. In addition, the first SiGe:B layer can include an atomic percentage (at-%) of germanium between 1 to 40 at-%, or between 5 to 30 at-%, or even between 15 to 20 at-%.

In some embodiments, the non-uniformity in germanium content (i.e., at-% Ge non-uniformity) in the first SiGe:B layer can be less than 1%, or less than 0.5%, or less than 0.2%, or less than 0.1%, or between 0.1% and 1%.

In some embodiments, the germanium content (at-%) within the first layer may not be constant, but rather may can be varied, such that the germanium content (and/or other components) may have a graded composition within the first layer. As a non-limiting example, the germanium content within the first layer may increase during the first deposition phase 402 from an initial germanium content of zero at-% up to a germanium content of greater than 40 at-% at the end of the first deposition phase 402. The germanium content (at-%) in the first layer can be increased in a linear manner, or alternatively the germanium content (at-%) in the first layer can be increased in a step-wise manner.

As previously stated, the first deposition phase 402 can be employed to epitaxially deposit a first boron doped silicon germanium layer. As a non-limiting example, the first SiGe:B layer can have a boron concentration greater than 1×10¹⁹ atom/cm³, or greater than 3×10¹⁹ atom/cm³, or greater than 5×10¹⁹ atom/cm³, or between 1×10¹⁹ atom/cm³ and 5×10¹⁹ atom/cm³. In some embodiments, the boron concentration (atom/cm³) non-uniformity in the first SiGe:B layer can be less than 3 percent (%), or less than 2 percent (%), or less than 1 percent (%), or between 1 and 3 percent (%).

Once the first layer (e.g., the first SiGe:B layer) has been epitaxially deposited during the first deposition phase 402, the multiphase deposition process 106 may proceed with a second deposition phase 404 (FIG. 4). In some embodiments, the second deposition phase 404 can comprise, introducing a second precursor gas into the chamber body to epitaxially deposit a second layer comprising silicon and germanium directly on the first layer. For example, the second deposition phase 404 can include, epitaxially depositing a fully strained second SiGe:B layer directly on the first SiGe:B layer.

In some embodiments, the second deposition phase 404 can comprise, introducing into the chamber body at least, one or more silicon containing gases, one or more germanium containing gases, one or more boron dopant gases, and one or more chlorine containing gases. All of the above process gases can also be introduced with or without a carrier gas, such as, for example, a hydrogen (H₂) gas.

In some embodiments, one or more silicon precursors, one or more germanium precursors, one or more boron dopant gases, and one or more chlorine containing gases, can be provided to a gas distribution assembly (not shown) at the injection end 226 (FIG. 2) of the reaction chamber assembly 200 as previously described herein above with reference to the first deposition phase 402 and therefore not repeated herein in the interest of brevity.

Exemplary silicon precursors, germanium precursors, boron dopant gases, and chlorine containing gases, employed in the second deposition phase 404 can include all those previously described previously with reference to the first deposition phase 402 and are therefore are not described again with reference to the second deposition phase 404 in the interest of brevity. In addition, as with the first deposition phase 402, in the second deposition phase 404, two or more silicon precursors, two or more germanium precursors, two or more boron dopant gases, and two or more chlorine containing gases can be employed in the second deposition phase 404 for the deposition of the second layer.

In some embodiments, in the second deposition phase 404, volumetric flow rates and flow ratios of the silicon precursors, the germanium precursors, the boron dopant gases, and the chlorine containing gases can vary in accordance with the desired composition of the second layer in the second deposition phase 402. By way of example, a flow rate of a silicon precursor can be between 10 sccm to 1000 sccm, or between 10 sccm to 500 sccm, or even between 10 sccm to 200 sccm. In addition, a flow rate of a germanium precursor can be between 10 sccm to 1000 sccm, or between 10 sccm to 250 sccm, or between 10 sccm to 100 sccm. In some embodiments, a flow rate of a boron dopant gases can be between 0.1 to 100 sccm, or between 0.2 sccm and 30 sccm, or even between 0.3 sccm and 15 sccm. In some embodiments, a flow rate of a chlorine-containing gas can be between 5 to 500 sccm, or between 10 sccm and 400 sccm, or even between 10 sccm and 300 sccm. It should be noted that all the above flow rates for the various process gases utilized during the first deposition phase and can be with or without a carrier gas.

In some embodiments, the second precursor gas may comprise, germane (GeH₄), diborane (B₂H₆), hydrochloric acid (HCl) vapor, and at least one of silane (SiH₄), disilane (Si₂H₆), and dichlorosilane (DCS). Therefore, in some embodiments, both the first precursor gas (employed in the first deposition phase 402) and the second precursor gas (employed in the second deposition phase 404) can both comprise germane (GeH₄), diborane (B₂H₆), hydrochloric acid (HCl) vapor, and at least one of silane (SiH₄), disilane (Si₂H₆), and dichlorosilane (DCS)

In some embodiments, the flow rate ratio of the germane (GeH₄) flow rate to the diborane (B₂H₆) flow rate into the chamber body during the second deposition phase 404 can remain substantially constant. For example, in some embodiments, the flow rate ratio of the germane (GeH₄) flow rate to the diborane (B₂H₆) flow rate remains substantially constant with a deviation away from a constant flow ratio of less than 10%, or less than 8%, or less than 6%, or less than 4%, or less than 2%, or less than 1%, or less than 0.5%, or even less than 0.1%. In some embodiments, the flow rate ratio of the germane (GeH₄) flow rate to the diborane (B₂H₆) flow rate into the chamber body during both the first deposition phase 402 and the second deposition phase 404 can remain substantially constant. For example, in some embodiments, the flow rate ratio of the germane (GeH₄) flow rate to the diborane (B₂H₆) flow rate remains substantially constant with a deviation away from a constant flow ratio of less than 10%, or less than 8%, or less than 6%, or less than 4%, or less than 2%, or less than 1%, or less than 0.5%, or even less than 0.1%.

In some embodiments, the second layer can comprise a fully strained second SiGe:B layer, which may form as a crystalline (e.g., monocrystalline) material overlying at least a portion of the first SiGe:B layer. Accordingly, at least a portion of the second layer may be monocrystalline and serve as a template for further epitaxial layers. In some cases, the entire second layer may be monocrystalline. In some embodiments, the second layer can comprise a fully strain second boron doped silicon germanium layer (i.e., the second SiGe:B layer) which can be epitaxially deposited directly on at least a portion of the underlying first SiGe:B layer. In such embodiments, the second SiGe:B layer can be epitaxially deposited in a fully strained state directly on at least a portion of the underlying first SiGe:B layer, i.e., the second SiGe:B layer is epitaxially deposited directly on at least a portion of the first SiGe:B layer without strain relaxation and without the formation of any dislocations resulting from said strain relaxation.

In some embodiments, the fully strained second SiGe:B layer may be epitaxially deposited during the second deposition phase 404 with a strain value in the second SiGe:B layer greater than 500 Megapascals (MPa), or greater than 550 MPa, or greater than 600 MPa, or greater than 650 MPa, or even greater than 700 MPa. In some embodiments, the fully strained second SiGe:B layer may be epitaxially deposited in the second deposition phase 404 with a strain value in the second SiGe:B layer between 500 MPa and 700 MPa, or between 550 MPa and 650 MPa, or even between 600 MPa and 650 MPa. In some embodiments, the second SiGe:B layer is fully compressively stained, with no strain relaxation, and with a compressive strain value of great than 500 Megapascals (MPa), or greater than 550 MPa, or greater than 600 MPa, or greater than 650 MPa, or even greater than 700 MPa. In some embodiments, the fully compressively strained second SiGe:B layer may be epitaxially deposited during the second deposition phase 404 with a compressive strain value between 500 MPa and 700 MPa, or between 550 MPa and 650 MPa, or even between 600 MPa and 650 MPa.

In some embodiments, the average layer thickness of the second SiGe:B epitaxially deposited during the second deposition phase 404 (FIG. 4) can be less than 80 nanometers, or less than 70 nanometers, or less than 60 nanometers, or less than 50 nanometers, or less than 40 nanometers, or less than 30 nanometers, or less than 20 nanometers, or less than 10 nanometers, or even less than 5 nanometers. In some embodiments, the average layer thickness of the fully strained second SiGe:B layer can be between 5 nanometers and 80 nanometers, or between 30 nanometers and 70 nanometers, or between 40 nanometers and 60 nanometers. In some embodiments, the fully strained second SiGe:B layer can have a thickness non-uniformity of less than 2 Angstroms, or less than 1 Angstroms, or less than 0.5 Angstroms, or between 0.5 Angstroms and 2 Angstroms.

In some embodiments, the fully strained second SiGe:B layer can include an atomic percentage (at-%) of silicon between 60 to 80 at-%, or between 60 to 90 at-%, or even between 60 at-% to 99 at-%. In addition, the fully strained second SiGe:B layer can include an atomic percentage (at-%) of germanium between 1 to 40 at-%, or between 5 to 30 at-%, or even between 15 to 20 at-%.

In some embodiments, the non-uniformity in germanium content (i.e., at-% Ge non-uniformity) in the fully strained second SiGe:B layer can be less than 1%, or less than 0.5%, or less than 0.2%, or less than 0.1%, or between 0.1% and 1%.

In some embodiments, the first layer comprises a first SiGe:B layer and the second layer comprises a second SiGe:B layer, wherein the germanium content (at-%) in the second SiGe:B layer is greater than the germanium content (at-%) in the first SiGe:B layer.

In some embodiments, the germanium content (at-%) within the second layer may not be constant, but rather may can be varied, such that the germanium content (and/or other components) may have a graded composition within the second layer. As a non-limiting example, the germanium content within the second layer may increase during the second deposition phase 404 from an initial germanium content equal to that of the first SiGe:B layer up to a germanium content greater than 70 at-% at the end of the second deposition phase 404. The germanium content (at-%) in the second layer can be increased in a linear manner, or alternatively the germanium content (at-%) in the first layer can be increased in a step-wise manner.

In some embodiments, the first SiGe:B layer has a germanium content (at-%) between 0.10 and 0.30, or between 0.15 and 0.40, and the second SiGe:B layer has a germanium content (at-%) between 0.30 and 0.65, or between 0.40 and 0.70, wherein the first SiGe:B layer and the second SiGe:B layer can both have an germanium content non-uniformity (i.e., at-% Ge non-uniformity) of less than 1%, or less than 0.5%, or less than 0.2%, or less than 0.1%, or between 0.1% and 1%.

As previously stated, the second deposition phase 404 can be employed to epitaxially deposit a fully strain second SiGe:B layer. As a non-limiting example, the fully strained second SiGe:B layer can have a boron concentration greater than 5×10¹⁹ atom/cm³, or greater than 8×10¹⁹ atom/cm³, or greater than 1×10²⁰ atom/cm³, or greater than 1.2×10²⁰ atom/cm³, or between 5×10¹⁹ atom/cm³ and 1.2×10²⁰ atom/cm³. In some embodiments, the boron concentration (atom/cm³) non-uniformity in the fully strained second SiGe:B layer can be less than 3 percent (%), or less than 2 percent (%), or less than 1 percent (%), or between 1 and 3 percent (%).

Once the second layer (e.g., the fully strain second SiGe:B layer) has been epitaxially deposited during the second deposition phase 404, the multiphase deposition process 106 may proceed with a third deposition phase 406 (FIG. 4). In some embodiments, the third deposition phase 406 can comprise, introducing third precursor gas into the chamber body to epitaxially deposit a third layer comprising silicon (Si) directly on the second layer. For example, the third deposition phase can include, epitaxially depositing a boron doped silicon layer (a Si:B layer) directly on the fully strained second SiGe:B layer.

The third deposition phase 406 can include introducing at least, one or more silicon containing gases, one or more boron dopant gases, and one or more chlorine containing gases. All of the above process gases can also be introduced with or without a carrier gas, such as, for example, a hydrogen (H₂) gas.

In some embodiments, one or more silicon precursors, one or more boron dopant gases, and one or more chlorine containing gases, can be provided to a gas distribution assembly (not shown) at the injection end 226 (FIG. 2) of the reaction chamber assembly 200 as previously described herein above with reference to the first deposition phase 402 and therefore not repeated herein in the interest of brevity.

Exemplary silicon precursors, boron dopant gases, and chlorine containing gases, employed in the third deposition phase 406 can include all those previously described previously with reference to the first deposition phase 402 and therefore are not described again with reference to the third deposition phase 406 in the interest of brevity. In the third deposition phase 406, two or more silicon precursors, two or more boron dopant gases, and two or more chlorine containing gases can be employed for the deposition of the third layer.

In some embodiments, in the third deposition phase 406, volumetric flow rates and flow ratios of the silicon precursors, the boron dopant gases, and the chlorine containing gases can vary in accordance with the desired composition of the third layer in the third deposition phase 406. By way of example, a flow rate of a silicon precursor can be between 10 sccm to 1000 sccm, or between 10 sccm to 500 sccm, or even between 10 sccm to 200 sccm. In some embodiments, a flow rate of a boron dopant gases can be between 0.1 to 100 sccm, or between 0.2 sccm and 30 sccm, or even between 0.3 sccm and 15 sccm. In some embodiments, a flow rate of a chlorine-containing gas can be between 5 to 500 sccm, or between 10 sccm and 400 sccm, or even between 10 sccm and 300 sccm. It should be noted that all the above flow rates for the various process gases utilized during the third deposition phase and can be with or without a carrier gas.

In some embodiments, the third precursor gas may comprise, diborane (B₂H₆), hydrochloric acid (HCl) vapor, and at least one of silane (SiH₄), disilane (Si₂H₆), and dichlorosilane (DCS).

In some embodiments, the third layer can comprise a boron doped silicon layer (the Si:B layer), which may form as a crystalline (e.g., monocrystalline) material overlying at least a portion of the second SiGe:B layer. Accordingly, at least a portion of the third layer may be monocrystalline and serve as a template for further epitaxial layers. In some cases, the entire third layer may be monocrystalline. In some embodiments, the third layer can comprise a fully strained boron doped silicon layer (i.e., the Si:B layer) which can be epitaxially deposited directly on at least a portion of the underlying fully strained second SiGe:B layer. In such embodiments, the Si:B layer can be epitaxially deposited in a fully strained state directly on at least a portion of the underlying fully strained second SiGe:B layer, i.e., the Si:B layer is epitaxially deposited directly on at least a portion of the second SiGe:B layer without strain relaxation and without the formation of any dislocations resulting from said strain relaxation.

In some embodiments, the average layer thickness of the third layer (i.e., the Si:B layer) epitaxially deposited during the third deposition phase 406 (FIG. 4) can be less than 50 nanometers, or less than 40 nanometers, or less than 30 nanometers, or less than 20 nanometers, or less than 10 nanometers, or even less than 5 nanometers. In some embodiments, the average layer thickness of the third layer comprising a Si:B layer can be between 5 nanometers and 50 nanometers, or between 5 nanometers and 30 nanometers, or between 5 nanometers and 15 nanometers. In some embodiments, the third layer comprising a Si:B layer can have a thickness non-uniformity of less than 2 Angstroms, or less than 1 Angstroms, or less than 0.5 Angstroms, or between 0.5 Angstroms and 2 Angstroms.

In some embodiments, each of the first boron doped SiGe:B layer, the fully strained second boron doped SiGe:B layer, and the boron doped Si:B layer encompassing the multilayer structure can all have a thickness non-uniformity of less than 2 Angstroms, or less than 1 Angstroms, or less than 0.5 Angstroms, or between 0.5 Angstroms and 2 Angstroms.

As previously stated, the third deposition phase 406 can be employed to epitaxially deposit a boron doped silicon layer (Si:B layer). As a non-limiting example, the Si:B layer can have a boron concentration greater than 1×10²¹ atom/cm³, or greater than 2×10²¹ atom/cm³, or greater than 3×10²¹ atom/cm³, or greater than 4×10²¹ atom/cm³, or between 1×10²¹ atom/cm³ and 4×10²¹ atom/cm³. In some embodiments, the boron concentration (atom/cm³) non-uniformity in the third layer comprising a Si:B layer can be less than 3 percent (%), or less than 2 percent (%), or less than 1 percent (%), or between 1 and 3 percent (%).

In some embodiments, the first SiGe:B layer, the second SiGe:B layer, and the silicon layer are all doped with boron, wherein the boron concentration (atom/cm³) in the silicon layer is greater than the boron concentration (atom/cm³) in the second SiGe:B layer, and the boron concentration in the second SiGe:B layer is greater than the boron concentration (atom/cm³) in the first SiGe:B layer.

In some embodiment, the third deposition phase 406 can be performed in the same chamber body used during the first deposition phase 402, and the second deposition phase 404. Alternatively, the third deposition phase 406 can be performed in another chamber body, such as another chamber body in the same cluster tool as the chamber body used during the first deposition phase 402, and the second deposition phase 404 or of another reactor system. The temperature and/or pressure for the third deposition phase 406 can be the same or similar to the temperature and/or pressure described above in connection with the first deposition phase 402 and the second deposition phase 404.

Once the third deposition phase 406 has been completed, the multiphase deposition process 106 can be terminated as illustrated in FIG. 4 by end step 408 which comprises, ending the multiphase deposition process 106. The conclusion of the multiphase deposition process 106 can also result in the end of the overall exemplary method 100, as illustrated by the end of process step 108 (FIG. 0.1).

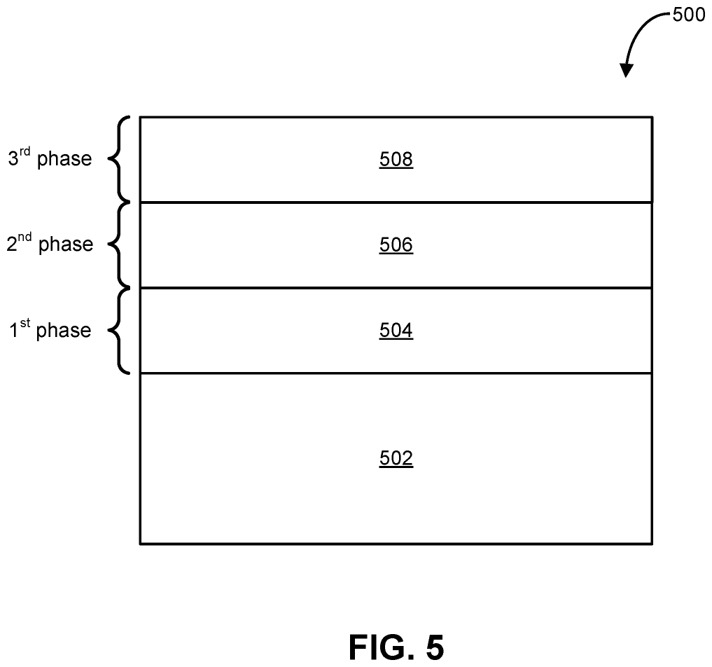

The embodiments of the disclosure further comprise structures, and particularly multilayer structures, formed using the methods of the present disclosure. As a non-limiting example, FIG. 5 illustrates a simplified cross-sectional schematic diagram of an exemplary multilayer structure 500 formed in accordance with the embodiments of the disclosure. In brief, the exemplary multilayer structure 500 (FIG. 5) can include a substrate 502, a first SiGe:B layer 504, a second SiGe:B layer, and a Si:B capping layer 508.

In more detail, the substrate 502 can comprise a monocrystalline silicon (Si) substrate, and in some embodiments a first SiGe:B layer 504 can be disposed directly on the Si substrate 502. The first SiGe:B layer 504 can be epitaxially deposited directly on the Si substrate 502 in a fully strained state such that the first SiGe:B layer 504 is free of strain relaxation induced dislocations. A fully strained second SiGe:B layer 506 can be disposed directly on the first SiGe:B layer 504. For example, the fully strained second SiGe:B layer 506 can be epitaxially deposited directly on the first SiGe:B layer 504 in a fully strained state such that the fully strained second SiGe:B layer 506 is free of strain relaxation induced dislocations. In some embodiments, a boron doped silicon capping layer (Si:B capping layer) can be disposed directly on the fully strain second SiGe:B layer. For example, the Si:B capping layer can be epitaxially deposited directly on the fully strained second SiGe:B layer in a fully strained state such that the Si:B capping layer is free of strain relaxation induced dislocations.

The thicknesses, thickness uniformities, compositions, composition non-uniformities, doping concentration, doping concentration non-uniformity, and strain levels of the first SiGe:B layer 504, the fully strained second SiGe:B layer 506, and the Si:B capping layer 508, have been previous described with reference to exemplary method 100 and are therefore not repeated here in the interested of brevity.

The multilayer structures formed by the methods disclosed herein may be employed in the fabricated of semiconductor devices, including but not limited to, planar transistors, FinFET devices, and gate-all-around devices. For example, during the fabrication of such devices, the multilayer structures of the present disclosure which can comprise a first SiGe:B layer, a fully strained second SiGe:B layer, and Si:B capping layer, can be employed as highly strained source and drain regions as part of a transistor type semiconductor device.

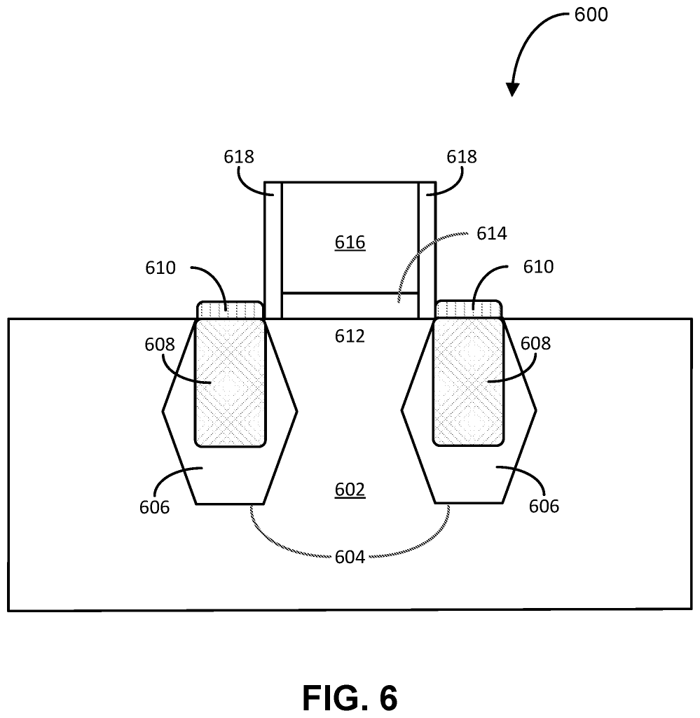

As a non-limiting example, FIG. 6 illustrates an exemplary planar transistor structure 600. For example, the exemplary planar transistor structure 600 may comprise a planar PMOS FET device.

In more detail, the exemplary planar transistor structure 600 may include a silicon substrate 602, which may include n-type dopants. Disposed in the substrate are the source and drain regions 604. In some the embodiments of the present disclosure, the source and drain regions 604 are deposited utilizing the methods disclosed herein. For example the source and drain regions 604 may comprise, a first SiGe:B layer 606 (as deposited during the first phase 402 of the multiphase deposition process 106 FIG. 4). The source and drain regions 604 can further comprise a fully strained second SiGe:B layer 608 (as deposited during the second phase 404 of the multiphase deposition process 106 of FIG. 4). The fully strained second SiGe:B layer 608 can be disposed directly on the underlying first SiGe:B layer 606. The source and drain regions 604 can further comprise, a Si:B capping layer 610 (as deposited during the third phase 404 of the multiphase deposition process 106 of FIG. 4). The Si:B capping layer 610 can be disposed directly on the underlying fully strained second SiGe:B layer 608. It should be noted that the source and drain regions 604 comprising, a first SiGe:B layer 606, a second fully strained SiGe:B layer 608, and a Si:B capping layer 610, may comprise a number of facets that can result due to the difference in growth rates from the different growth surfaces of the source and drain trench regions from which deposition is performed.

The exemplary planar transistor structure 600 may further comprise a channel region 612, which may be disposed between the source and drain regions 604. In addition, the planar transistor structure 600 may further comprise, a gate dielectric 614, and a gate electrode 616 disposed over the channel region 612. In addition, gate spacers 618 may disposed over the substrate 602.

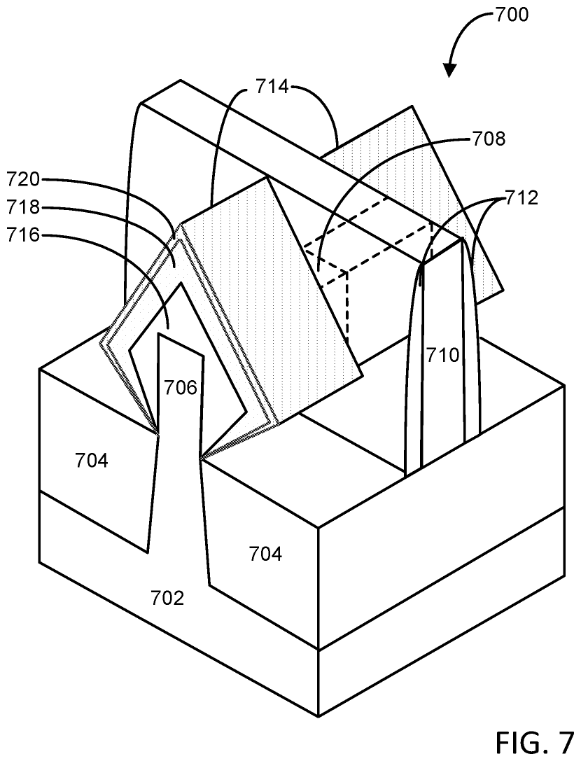

As a further non-limiting example, FIG. 7 illustrates an exemplary double gate MOSFET structure, commonly referred to as a FinFET 700. The exemplary FinFET 700 (FIG. 7) may include a substrate 702, which may comprise a bulk monocrystalline silicon (Si) substrate. The substrate 702 can be doped with n-type dopants and the FinFET 700 in this example can comprise a PMOS type FinFET.

In more detail, the FinFET 700 may include isolation regions 704, which may comprise shallow trench isolation (STI) regions. The exemplary FinFET 700 may also include a Fin structure 706 extending over the top surfaces of the isolation regions 704, the portion of the Fin structure 706 buried beneath the additional device layers is shown by the dashed lines and particularly includes the channel region 708. A gate dielectric (not shown) can be disposed over the sidewalls of the Fin structure 406 and the gate dielectric may comprise a silicon oxide or a high-k dielectric material. A gate electrode 710 may be disposed on the gate dielectric for providing electrical contact to the channel region 708, the channel region 708 being the portion of the Fin structure 706 covered by the gate dielectric and the gate electrode. The exemplary FinFET 700 may also comprise gate spacers 712, which are disposed on the sidewalls of the gate electrode 710.

The exemplary FinFET 700 (FIG. 7) may further comprise source and drain regions 714 disposed over the Fin structure 706 and adjacent to the channel region 708. In some embodiments, the source and drains regions 714 may be deposited according the methods of the present disclosure. For example, the source and drain regions 714 may comprise, a first SiGe:B layer 716 (as deposited during the first deposition phase 402 of the multiphase deposition process 106 FIG. 4). The source and drain regions 714 can further comprise a fully strained second SiGe:B layer 718 (as deposited during the second deposition phase 404 of the multiphase deposition process 106 of FIG. 4). The fully strained second SiGe:B layer 718 can be disposed directly on the underlying first SiGe:B layer 716. The source and drain regions 714 can further comprise, a Si:B capping layer 720 (as deposited during the third deposition phase 404 of the multiphase deposition process 106 of FIG. 4). The Si:B capping layer 720 can be disposed directly on the underlying fully strained second SiGe:B layer 718. It should be noted that the source and drain regions 714 comprising the first SiGe:B layer 716, the fully strained second SiGe:B layer 718, and the Si:B capping layer 720, may comprise a number of facets that may result due to the difference in growth rates on the different facets of the Fin structure 706.

The embodiments of the present disclosure also include partially fabricated semiconductor device structures, wherein the partially fabricated device structures may comprise partially fabricated planar transistors and FinFETs including the multilayer structures of the present disclosure. The multilayer structures and the methods described herein for forming such multilayer structures may also be utilized and included in next generation three-dimensional (3D) device structures, such as, but not limited to, gate-all-around device structures, nanosheet device structures, forksheet device structures, and complementary FET (CFET) device structures. For example, the multilayer structures of the present disclosure can comprise at least a portion of a partially fabricated gate-all-around device structure, a partially fabricated nanosheet device structure, a partially fabricated forksheet device structure, and a complementary FET (CFET) device structure

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for depositing a multilayer structure on a substrate, the method comprising:
seating a substrate on a substrate support disposed in a chamber body, the chamber body having an upper wall and a lower wall;
heating the substrate to a deposition temperature employing at least an upper heater element array supported above the upper wall of the chamber body;
providing a controller in communication with at least the upper heater element array, wherein the controller throttles power to at least the upper heater element array according to a set of optical temperature measurements communicated to the controller from at least a first pyrometer and a second pyrometer, the first pyrometer and the second pyrometer being supported above the upper heater element array and being optically coupled to a surface of the substrate over a first acquisition area and a second acquisition area, wherein the second acquisition area is radially distal from the first acquisition area; and
depositing a multilayer structure over the substrate employing a multiphase deposition process which includes at least three deposition phases comprising;
epitaxially depositing a first SiGe:B layer over the substrate during a first deposition phase;
epitaxially depositing a fully strained second SiGe:B layer directly over the first SiGe:B layer during a second deposition phase; and
epitaxially depositing a Si:B layer directly on the fully strained second SiGe:B layer,
wherein the boron concentration (atom/cm³) non-uniformity in the first SiGe:B layer, the fully strained second SiGe:B layer, and the Si:B layer is less than 3%.

2. The method of claim 1, wherein the upper wall of the chamber body extends longitudinally between an injection end and a longitudinally opposite exhaust end, and the lower wall is below and parallel relative to the upper wall.

3. The method of claim 1, wherein the chamber body comprises an arcuate, or dome-like shape.

4. The method of claim 1, wherein the first SiGe:B layer has a germanium content (at-%) between 0.15 and 0.40 and the fully strained second SiGe:B layer has a germanium content (at-%) between 0.40 and 0.70, and wherein the first SiGe:B layer and the fully strained second SiGe:B layer have a germanium content (at-%) non-uniformity of less than 0.5%.

5. The method of claim 1, wherein each of the first SiGe:B layer, the fully strained second SiGe:B layer, and the Si:B layer, have a thickness non-uniformity of less than 1 Angstrom.

6. A multilayer structure comprising at least, a first SiGe:B layer, a fully strained second SiGe:B layer disposed directly on the first SiGe:B layer, and a Si:B layer disposed directly on the fully strained second SiGe:B layer, wherein the multilayer structure forms at least a portion of a source or drain region of a semiconductor transistor device structure and is formed by the method of claim 1.

7. A method for forming a semiconductor structure, the method comprising:
seating a substrate within a chamber body;
regulating a temperature profile across an entire upper surface of the substrate to a temperature non-uniformity of less than 1° C., by employing a temperature feedback control procedure which operates during each individual phase of a multiphase deposition process, wherein the temperature feedback control procedure comprises;
acquiring at least two independent sets of optical temperature measurements from at least two separate areas on the upper surface of the substrate; and
throttling heating of the substrate according to a temperature differential or a temperature gradient across the upper surface of the substrate as determined by the at least two independent sets of optical temperature measurements; and
depositing a multilayer structure employing the multiphase deposition process, wherein the multiphase deposition process includes at least three deposition phases comprising;
introducing a first precursor gas into the chamber body to epitaxially deposit a first layer comprising silicon and germanium on the substrate during a first deposition phase;
introducing a second precursor gas into the chamber body to epitaxially deposition a second layer comprising silicon and germanium directly on the first layer during a second deposition phase; and
introducing a third precursor gas into the chamber body to epitaxially deposit a third layer comprising silicon directly on the second layer during a third deposition phase.

8. The method of claim 7, wherein throttling the heating of the substrate further comprising, regulating power supplied to a upper heater element array disposed above the chamber body based on the at least two independent sets of optical temperature measurements.

9. The method of claim 8, wherein the at least two independent sets of optical temperature measurements comprise at least a first set of optical temperature measurements (T₁) acquired from a first acquisition area of the upper surface of the substrate by a first pyrometer supported above the upper heater elements array, and at least a second set of optical temperature measurements (T₂) acquired from a second acquisition area of the upper surface of the substrate by a second pyrometer supported above the upper heater elements array, wherein the first acquisition area and the second acquisition area are separated from one another.

10. The method of claim 9, wherein the first pyrometer is arranged along a first optical axis and the second pyrometer is arranged along a second optical axis, the second optical axis being radially outward of the first optical axis.

11. The method of claim 7, wherein the first layer comprises a first SiGe layer and the second layer comprises a second SiGe layer, wherein the germanium content (at-%) in the second SiGe layer is greater than the germanium content (at-%) in the first SiGe layer.

12. The method of claim 11, wherein the first SiGe layer, the second SiGe layer, and the third layer are all doped with boron, wherein the boron concentration (atom/cm³) in the third layer is greater than the boron concentration (atom/cm³) in the second SiGe layer, and the boron concentration in the second SiGe layer is greater than the boron concentration (atom/cm³) in the first SiGe layer.

13. The method of claim 12, wherein the boron concentration (atom/cm³) non-uniformity in the third layer, the first SiGe layer, and the second SiGe layer is less than 3 percent (%).

14. The method of claim 11, wherein the germanium content (at-%) non-uniformity in the first SiGe layer and in the second SiGe layer is less than 0.5 percent (%).

15. The method of claim 7, wherein the first precursor gas and the second precursor gas both comprise germane (GeH₄), diborane (B₂H₆), hydrochloric acid (HCl) vapor, and at least one of silane (SiH₄), disilane (Si₂H₆), and dichlorosilane (DCS).

16. The method of claim 7, wherein a flow rate ratio of germane (GeH₄) flow rate to diborane (B₂H₆) flow rate into the chamber body during the both the first deposition phase and the second deposition phase remains substantially constant.

17. The method of claim 7, wherein deposition temperature remains substantially constant during the first deposition phase, the second deposition phase, and the third deposition phase, of the multiphase deposition process.

18. The method of claim 11, wherein the second SiGe layer is fully compressively strained with no strain relaxation, and with a compressive strain value of greater than 500 Megapascals (MPa).

19. The method of claim 7, wherein the multiphase deposition process is a selective deposition process, wherein the selective deposition process deposits the first layer, the second layer, and third layer, over a crystalline material as opposed to depositing over a non-crystalline material, and wherein the multiphase deposition process is uniformly selective over the entire upper surface of the substrate.

20. A multilayer structure comprising, three or more layers including at least a first boron doped SiGe layer, a fully compressively strained second boron SiGe layer disposed directly on the first boron doped SiGe layer, and a boron doped silicon capping layer disposed directly on the fully compressively strained second SiGe layer, wherein the multilayer structure forms at least a portion of a source or drain region of a semiconductor transistor device structure and is formed by the method of claim 1.
